(19) United States
(12) Patent Application Publication
(10) Pub. No.: US 2015/0101857 A1
(43) Pub. Date: Apr. 16, 2015

(54) PRINTED CIRCUIT BOARD AND METHOD FOR MANUFACTURING THE SAME

(71) Applicant: Samsung Electro-Mechanics Co., Ltd., Suwon-Si (KR)

(72) Inventors: Da Hee KIM, Suwon-Si (KR); Jung Hyun PARK, Suwon-Si (KR); Yong Yoon CHO, Suwon-Si (KR); Sung Won JEONG, Suwon-Si (KR); Gi Ho HAN, Suwon-Si (KR); Ki Hwan KIM, Suwon-Si (KR)

(73) Assignee: Samsung Electro-Mechanics Co., Ltd., Suwon-Si (KR)

(21) Appl. No.: 14/500,953

(22) Filed: Sep. 29, 2014

(30) Foreign Application Priority Data
Oct. 14, 2013 (KR) 10-2013-0122153

(51) Int. Cl. H05K 1/02; H05K 3/46; H05K 3/02; H05K 3/00; H05K 1/11; H05K 3/06

(52) U.S. Cl. CPC H05K 1/0271; H05K 1/115; H05K 3/067; H05K 3/025; H05K 3/007; H05K 3/467; H05K 3/4682; H05K 3/4661
USPC 174/262; 216/17; 29/847

(57) ABSTRACT

There is provided a method for manufacturing a printed circuit board including: preparing a substrate having a conductive layer formed on at least a portion thereof; forming an insulating layer formed with an opening through which a portion of the conductive layer is exposed on the substrate; forming a plating seed layer on the insulating layer and the exposed conductive layer; forming an electroplating layer on the plating seed layer by overplating the plating seed layer; and etching the overplated portion in a lump to form a circuit layer in the opening.

### CROSS-REFERENCE TO RELATED APPLICATION

This application claims the benefit of Korean Patent Application No. 10-2013-0122153, filed on Oct. 14, 2013, entitled “Printed Circuit Board And Method For Manufacturing The Same” which is hereby incorporated by reference in its entirety into this application.

### BACKGROUND

The present disclosure relates to a printed circuit board and a method for manufacturing the same, and more particularly, to a printed circuit board including a circuit layer having a uniformly plated thickness and a method for manufacturing the same.

Recently, with the miniaturization and multi-functionality of electronic components, the traditionally used printed circuit board has increasingly required high-integrated thin products having a heat radiation property, and the like which may be maximized by applying fine patterning, a stack-via structure, and the like. Therefore, to form a via and a fine pattern having various shapes, sizes, and thicknesses, it is general to form a plating layer using an electroplating scheme.

However, as electronic devices require a rapid response speed, the stack-via scheme which has been used to manufacture the high-integrated thin products having the heat radiation property also faces with a situation in which heat from a semiconductor is insufficiently removed. To solve the above problem, holes larger than a signal transfer hole which has been traditionally used are required, in which the holes are formed to have a larger thickness by laser processing or a batch manufacturing method.

However, when an insulating film such as a dry film is developed or processed and then is plated at a larger thickness, since a difference in fill platability between an outer wall of the insulating film and a base plating portion occurs, it is difficult to make a plated thickness uniform in a large area substrate.

To solve the above problem, a mechanical polishing process has been used to make the plated thickness uniform. However, as an area of a panel is increased, the mechanical polishing has a difficulty in making the plated thickness uniform and has a limitation in making the plated thickness uniform due to the occurrence of physical influences such as a warpage of a substrate due to the polishing.

According to the typical method for making a plated thickness uniform by the mechanical polishing, a portion formed with the plating layer is first opened using an insulating layer film and then the plating layer is formed. In this case, a deviation in the thickness of the plating layer occurs in the large-area panel according to a size and a shape of an opening. The deviation in the thickness of the plating layer ranges from about 20 to 50 μm. To reduce the deviation in the thickness of the plating layer, a portion at which a circuit layer such as a via and a circuit pattern protrudes over the insulating layer film is mechanically polished.

The mechanical polishing process which is a process of reducing a plating deviation is greatly affected by a wiring design of the plating layer, and therefore has a limitation in reducing the deviation in the plated thickness. Further, the mechanical polishing process may cause a warpage and a scratch of the panel due to a physical impact applied to the large area panel at the time of the mechanical polishing.

Further, when the holes are formed on the stacked insulating layer by the laser processing and then the electroplating is performed, defects such as dimple frequently occur due to the difference in electroplatability. The problem of the dimple defect may be improved by the electroplating scheme which is changed by changing sulfuric acid concentration. However, the electroplating scheme steadily causes the dimple defect and has a limitation in making the plated thickness uniform due to an aspect ratio, that is, a ratio of length to width of the portion to be plated due to the thickness of the stacked film or the dry film.

Patent Document described in the following Related Art Document discloses a method for manufacturing a printed circuit board which may basically remove a phenomenon that an overcharging structure of the via occurs, implement a micro circuit, improve reliability inside the via. However, the following Patent Document may remove the phenomenon that the overcharging structure of the via occurs, but does not yet solve the problem in that the plated thickness is non-uniform and the dimple occurs due to the difference in the ratio of length to width of the portion to be plated according to the thickness of the stacked film or the dry film and the wiring design.

Therefore, a need exists for a printed circuit board and a method for manufacturing the same capable of solving the non-uniformity of the plated thickness and the occurrence of the dimple due to the difference in the ratio of length to width of the portion to be plated according to the thickness of the stacked film or the dry film and the wiring design which may occur in the electroplating scheme.

### RELATED ART DOCUMENT

### Patent Document

(Patent Document 1) KR10-2010-0068747 A

### SUMMARY

An aspect of the present disclosure provides a method for manufacturing a printed circuit board capable of solving non-uniformity of a plated thickness and occurrence of a dimple due to a difference in a ratio of length to width of a portion to be plated according to a thickness of a stacked film or a dry film and a wiring design which may occur in the electroplating scheme, making a plated thickness of a via or a circuit pattern uniform, and reducing a stress of a substrate by preventing a warpage and a scratch of the substrate.

Another aspect of the present disclosure provides a printed circuit board capable of solving non-uniformity of a plated thickness and occurrence of a dimple due to a difference in a ratio of length to width of a portion to be plated according to a thickness of a stacked film or a dry film and a wiring design which may occur in the electroplating scheme, making a plated thickness of a via or a circuit pattern uniform, and reducing a stress of a substrate by preventing a warpage and a scratch of the substrate.

According to an aspect of the present disclosure, a method for manufacturing a printed circuit board may include: preparing a substrate having a conductive layer formed on at least a portion thereof; forming an insulating layer formed with an opening through which a portion of the conductive layer is exposed on the substrate; forming a plating seed layer on the insulating layer and the exposed conductive layer; forming an electroplating layer on the plating seed layer by overplating the plating seed layer; and etching the overplated portion in a lump to form a circuit layer in the opening.

The forming of the electroplating layer may include overplating the plating seed layer until an exposed surface of the electroplating layer is planarized.

The etching of the overplated portion in a lump may include etching the overplated portion in a lump until the insulating layer is exposed.

The etching of the overplated portion in a lump may include etching the overplated portion in a lump so that the electroplating layer and the plating seed layer of 1 μm or less remains outside the insulating layer and the electroplating layer and the plating seed layer of 1 μm or less which are formed outside the insulating layer may serve as the plating seed layer for forming additional circuit layer.

The forming of the plating seed layer may include forming the plating seed layer on the insulating layer and the exposed conductive layer by an electroless plating process or a sputtering process.

In the etching of the overplated portion in a lump, the circuit layer formed in the opening by the etching in a lump may include a via or a circuit pattern.

The conductive layer may include a via or a circuit pattern.

The conductive layer may include a copper foil formed over the substrate, wherein the method may further include: after the etching of the overplated portion in a lump, removing the insulating layer and a copper foil contacting the insulating layer by an etching process and forming a stacked insulating layer at the removed position.

The insulating layer may include a photosensitive resin material and the opening of the insulating layer may be formed by attaching the photosensitive resin material to the substrate and by exposing and developing processes.

The insulating layer may include a stacked film and the opening of the insulating layer may be formed by attaching the stacked film to the substrate and by laser processing.

According to another aspect of the present disclosure, a method for manufacturing a printed circuit board may include: preparing a carrier having both surfaces formed with copper foils formed to be peeled; forming an insulating layer formed with an opening through which a portion of the copper foils is exposed on the carrier; forming a plating seed layer on the insulating layer and the exposed copper foil; forming an electroplating layer on the plating seed layer by overplating the plating seed layer; etching the overplated portion in a lump to form a circuit layer in the opening; stacking a plurality of insulating layers and circuit layers on the circuit layer; separating the carrier from a stacked structure of an upper layer and a lower layer; and removing the copper foils of the carrier which are each attached to the stacked structure of the upper layer and the lower layer.

The forming of the electroplating layer may include overplating the plating seed layer until an exposed surface of the electroplating layer is planarized.

The etching of the overplated portion in a lump may include etching the overplated portion in a lump until the insulating layer is exposed.

The etching of the overplated portion in a lump may include etching the overplated portion in a lump so that the electroplating layer and the plating seed layer of 1 μm or less remains outside the insulating layer and the electroplating layer and the plating seed layer of 1 μm or less which are formed outside the insulating layer may serve as the plating seed layer for forming additional circuit layer.

The forming of the plating seed layer may include forming the plating seed layer on the insulating layer and the exposed copper foil by an electroless plating process or a sputtering process.

In the etching of the overplated portion in a lump, the circuit layer formed in the opening by the etching in a lump may include a via or a circuit pattern.

The insulating layer may include a photosensitive resin material and the opening of the insulating layer may be formed by attaching the photosensitive resin material to the copper foil and by exposing and developing processes.

The insulating layer may include a stacked film and the opening of the insulating layer may be formed by attaching the stacked film to the copper foil and by laser processing.

According to still another aspect of the present disclosure, a printed circuit board may include: an insulating layer formed with at least one opening; and a circuit layer formed in the at least one opening, wherein the circuit layer may include a plating seed layer including a bottom portion and side walls surrounded with the insulating layer; and an electroplating layer surrounded with the bottom portion and the side walls of the plating seed layer.

The circuit layer may include a via or a circuit pattern and the via or the circuit pattern may be formed by forming the plating seed layer on the insulating layer and a portion exposed by the opening, forming an electroplating layer by overplating the plating seed layer, and etching the overplated portion in a lump.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1A to 1F are process cross-sectional views illustrating a method for manufacturing a printed circuit board according to a first exemplary embodiment of the present disclosure;

FIG. 1G is a diagram illustrating the printed circuit board according to the exemplary embodiment of the present disclosure;

FIGS. 2A to 2G are process cross-sectional views illustrating a method for manufacturing a printed circuit board according to a second exemplary embodiment of the present disclosure;

FIGS. 3A to 3G are process cross-sectional views illustrating a method for manufacturing a printed circuit board according to a third exemplary embodiment of the present disclosure; and

FIGS. 4A to 4F are process cross-sectional views illustrating a method for manufacturing a printed circuit board according to a fourth exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

Method for Manufacturing Printed Circuit Board According to First Exemplary Embodiment

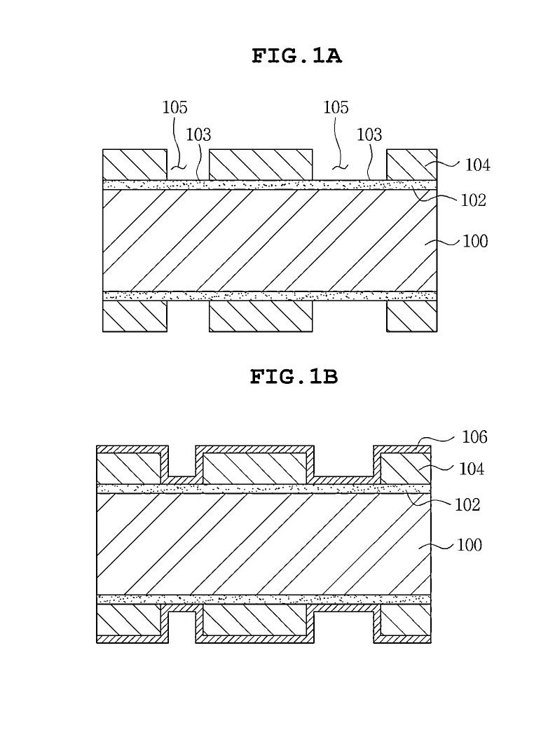

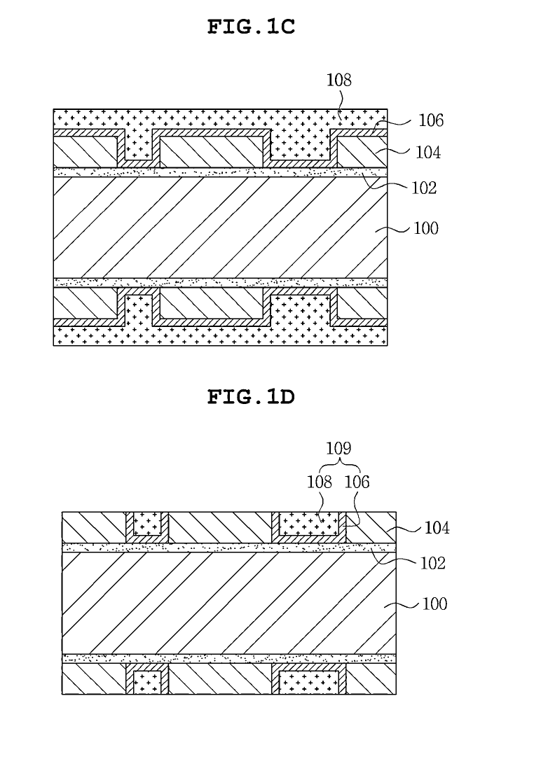

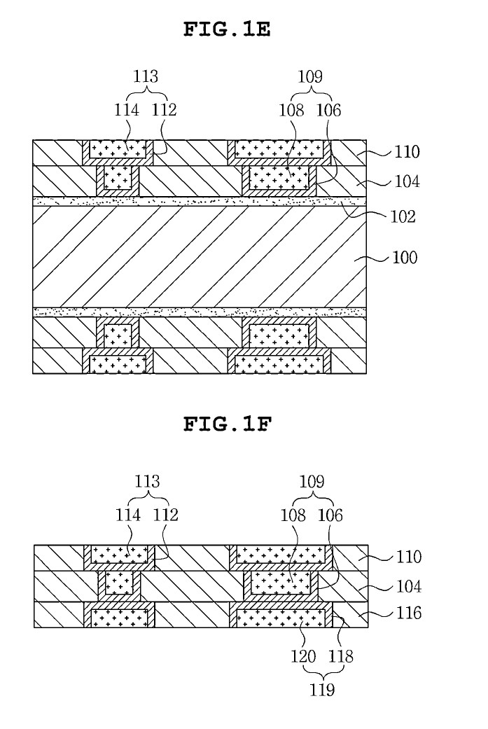

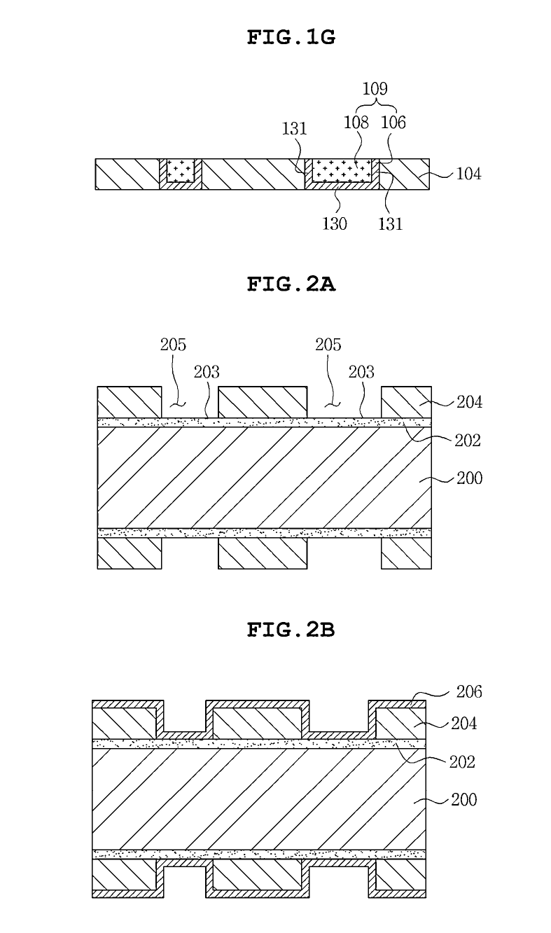

FIGS. 1A to 1F are process cross-sectional views sequentially illustrating a method for manufacturing a printed circuit board according to a first exemplary embodiment of the present disclosure.

Hereinafter, the method for manufacturing a printed circuit board according to the first exemplary embodiment of the present disclosure will be described with reference to FIGS. 1A to 1F.

The typical method forms only an opening on an insulating layer film and then directly performs electroplating and therefore makes a thickness of a plating layer, which will be formed as a circuit layer including a via or a circuit pattern, non-uniform due to a difference in platability between an insulating portion without a conductive property and a base plating portion with a conductive property.

According to an exemplary embodiment of the present disclosure, a plating seed layer is formed over the insulating layer and the base plating portion to remove the difference in electroplatability between the insulating layer and the base plating portion and is overplated with the electroplating by a panel plating scheme, and then the overplated portion is etched in a lump to make the thickness of the plating layer, which will be formed as the circuit layer, uniform, such that the printed circuit board including the via or the circuit pattern having a uniform thickness may be manufactured.

Referring to FIG. 1A, a substrate 100 on which a copper foil 102 is formed is prepared and then an insulating layer 104 formed with an opening 105 through which a portion of the copper foil 102 is exposed is formed on the substrate 100. The insulating layer 104 may include a liquid photosensitive resin as a photosensitive resin material or a dry film resist (DRF), but is not particularly limited thereto.

The opening 105 formed on the insulating layer 104 may be formed by exposing and developing processes after the insulating layer 104 is attached to the copper foil 102 formed on the substrate 100. According to the method for manufacturing a printed circuit board according to the first exemplary embodiment of the present disclosure, the photosensitive resin material is used as the insulating layer 104 and the opening 105 is formed on the insulating layer 104 by using a photo method which is an exposure method.

Next, as illustrated in FIG. 1B, the whole surface of the insulating layer 104 formed with the opening 105 and the base plating part 103 exposed through the opening 105 in the copper foil 102 is plated at 1 μm or less by a sputtering process, thereby forming a plating seed layer 106. The plating seed layer 106 may be formed by using the sputtering process or an electroless plating process.

When the plating seed layer 106 is formed over the insulating layer 104 and the base plating part 103, a difference in electroplatability between the insulating layer 104 and the base plating part 103 is removed. Referring to FIG. 1B, it may be appreciated that the plating seed layer 106 is formed over the insulating layer 104, including sides of the insulating layer 104.

Next, as illustrated in FIG. 1C, an electroplating layer 108 is formed on the plating seed layer 106 by performing the electroplating. The plating seed layer 106 is overplated until a surface of the electroplating layer 108 is planarized by controlling a frequency of the electroplating and a current density. For example, the electroplating layer 108 is overplated so that an outermost portion of the plating seed layer 106 exceeds around 1 to 5 μm.

According to the first exemplary embodiment of the present disclosure, the overplated thickness ranges from 1 to 5 μm, but is not particularly limited thereto.

Since the plating seed layer 106 is also formed on the surface of the insulating layer 104 by the sputtering process, electric conductivity is increased and thus the electroplating is performed without a problem of fillability at the time of the electroplating and as the electroplating is performed, the outermost portion of the electroplating layer 108 is formed to be planarized by the panel plating scheme.

Next, as illustrated in FIG. 1D, the overplated portion of the electroplating layer 108 and a portion of the plating seed layer 106 are etched in a lump. For example, the electroplating layer 108 and a portion of the plating seed layer 106 are etched in a lump by half etching. The etching is performed at 2 to 6 μm until the insulating layer 104 is exposed. When the etching is completed, a thickness of a circuit layer 109 formed of the electroplating layer 108 and the plating seed layer 106 becomes uniform while the outermost portion of the electroplating layer 108 and the plating seed layer 106 is planarized. Therefore, the circuit layer 109 having a uniform thickness may be formed.

Meanwhile, when the dry film resist (DFR) is used as the insulating layer 104, the insulating layer 104 is removed and then the portion from which the insulating layer 104 is removed may be formed with another insulating layer.

According to the exemplary embodiment of the present disclosure, the circuit layer 109 formed of the electroplating layer 108 and the plating seed layer 106 is the via for interlayer connection, but the exemplary embodiment of the present disclosure is not limited thereto, and therefore the circuit layer 109 formed of the electroplating layer 108 and the plating seed layer 106 may be a thick circuit pattern.

Meanwhile, according to the first exemplary embodiment of the present disclosure, the substrate 100 is a carrier having both surfaces formed with the copper foils 102 which may be peeled.

As described above, the method for manufacturing a printed circuit board including the via which is the circuit layer 109 having a uniform thickness will be described with reference to FIGS. 1E and 1F.

As illustrated in FIG. 1E, the insulating layer 110, the plating seed layer 112, and the electroplating layer 114 are formed on the via 109 having a uniform thickness by using a similar process to the process illustrated in FIGS. 1A to 1D, thereby forming a first circuit pattern 113 having a uniform thickness.

Next, as illustrated in FIG. 1F, the carrier 100 is separated from a stacked structure of an upper layer and a lower layer, the copper foil 102 is removed, and then the insulating layer 116, the plating seed layer 118, and the electroplating layer 120 are formed under the via 109 having a uniform thickness by using a similar process to the process illustrated in FIGS. 1A to 1D, thereby forming a second circuit pattern 119 having a uniform thickness. Finally, as illustrated in FIG. 1F, the printed circuit board including the plating layer having a uniform thickness may be manufactured.

The exemplary embodiment of the present disclosure describes the method for manufacturing a printed circuit board in which three layers are stacked but is not limited thereto, and therefore a multilayered printed circuit board may be manufactured by stacking a plurality of insulating layers and circuit layers having a uniform thickness.

Printed Circuit Board According to Exemplary Embodiment

FIG. 1G is a diagram illustrating a printed circuit board according to an exemplary embodiment of the present disclosure.

As illustrated in FIG. 1G, the printed circuit board according to the exemplary embodiment of the present disclosure is a printed circuit board formed by separating the carrier 100 from the stacked structure of the upper layer and the lower layer and removing the copper foil 102 when viewed from the process cross-sectional view illustrated in FIG. 1D.

The printed circuit board according to the exemplary embodiment of the present disclosure illustrated in FIG. 1G includes the insulating layer 104 formed with at least one opening and the circuit layer 109 embedded in the at least one opening.

The circuit layer 109 includes the plating seed layer 106 which includes a bottom portion 130 and side walls 131 surrounded by the insulating layer 104 and the electroplating layer 108 embedded in a space formed by the bottom portion 130 and the side walls 131 of the plating seed layer 106. The circuit layer 109 may include the via or the circuit pattern.

As illustrated in FIG. 1G, the printed circuit board according to the exemplary embodiment of the present disclosure is a printed circuit board formed by separating the carrier 100 from the stacked structure of the upper layer and the lower layer and removing the copper foil 102 when viewed from the process cross-sectional view illustrated in FIG. 1D.

The circuit layer 109 of the printed circuit board according to the exemplary embodiment of the present disclosure as illustrated in FIG. 1G is formed by, for example the process illustrated in FIGS. 1A to 1D and therefore the outermost portion of the circuit layer 109 is planarized and thus the thickness of the circuit layer 109 becomes uniform. Therefore, it is possible to improve characteristics and reliability of the printed circuit board.

Method for Manufacturing Printed Circuit Board According to Second Exemplary Embodiment

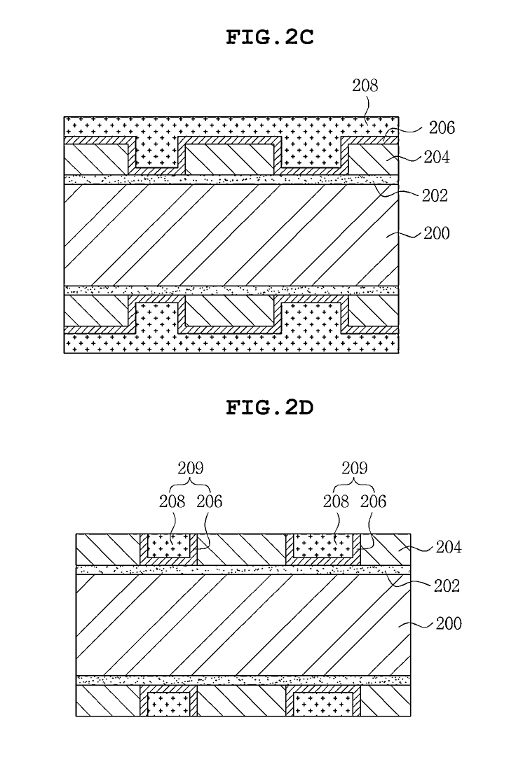

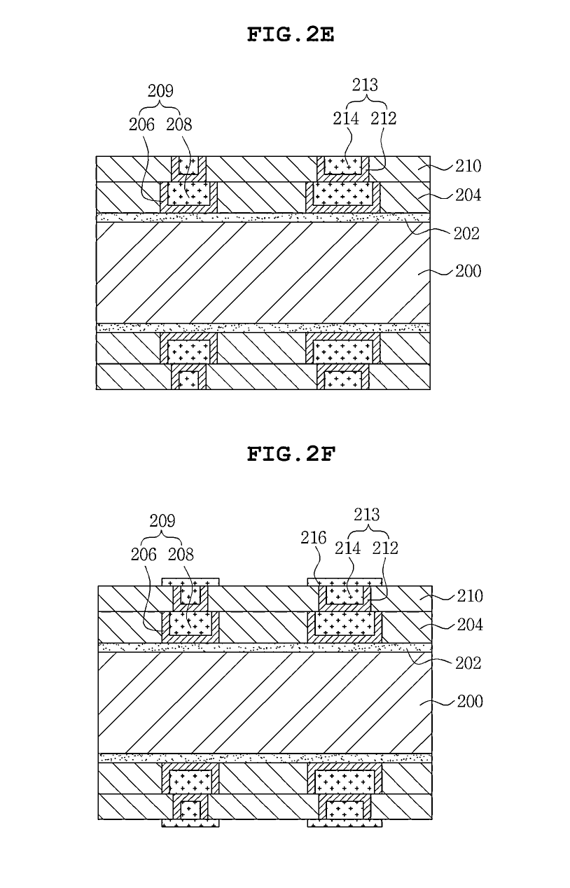

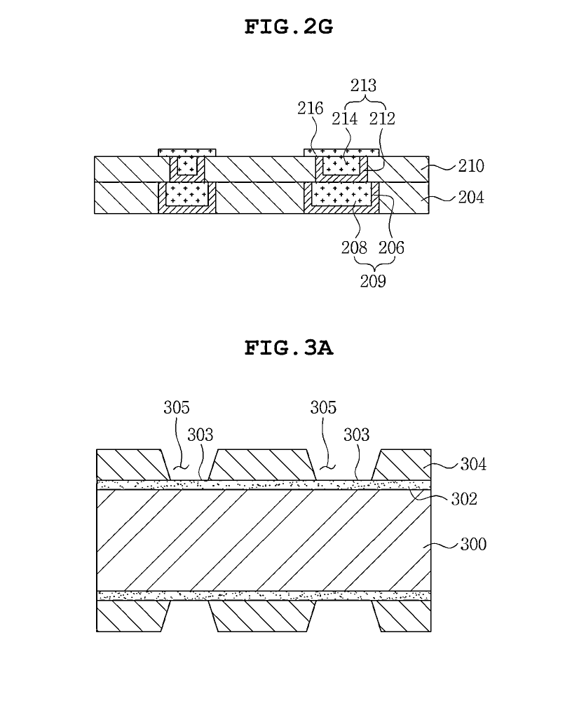

FIGS. 2A to 2G are process cross-sectional views illustrating a method for manufacturing a printed circuit board according to a second exemplary embodiment of the present disclosure.

Hereinafter, the method for manufacturing a printed circuit board according to the second exemplary embodiment of the present disclosure will be described with reference to FIGS. 2A to 2G.

The first exemplary embodiment of the present disclosure describes the method for manufacturing a printed circuit board after the via is formed as the circuit layer 109. A second exemplary embodiment of the present disclosure will describe the method for manufacturing a printed circuit board after the circuit pattern is formed as the circuit layer 109.

Referring to FIG. 2A, a substrate 200 on which a copper foil 202 is formed is prepared and then an insulating layer 204 formed with an opening 205 through which a portion of the copper foil 202 is exposed is formed on the substrate 200. The insulating layer 204 may include a liquid photosensitive resin as a photosensitive resin material or a dry film resist (DRF), but is not particularly limited thereto.

The opening 205 formed on the insulating layer 204 may be formed by the exposing and developing processes after the insulating layer 204 is attached to the copper foil 202 formed on the substrate 200. According to the method for manufacturing a printed circuit board according to the second exemplary embodiment of the present disclosure, the photosensitive resin material is used as the insulating layer 204 and the opening 205 is formed on the insulating layer 204 by using the photo method which is the exposure method.

Next, as illustrated in FIG. 2B, the whole surface of the insulating layer 204 formed with the opening 205 and the base plating part 203 exposed through the opening 205 in the copper foil 202 is plated at 1 μm or less by the sputtering process, thereby forming a plating seed layer 206. The plating seed layer 206 may be formed by using the sputtering process or the electroless plating process.

According to the exemplary embodiment of the present disclosure, when the plating seed layer 206 is formed over the insulating layer 204 and the base plating part 203, a difference in electroplatability between the insulating layer 204 and the base plating part 203 is removed.

Next, as illustrated in FIG. 2C, an electroplating layer 208 is formed on the plating seed layer 206 by performing the electroplating. The plating seed layer 206 is overplated until a surface of the electroplating layer 208 is planarized by controlling a frequency of the electroplating and a current density. For example, the electroplating layer 208 is overplated so that an outermost portion of the plating seed layer 206 exceeds around 1 to 5 μm.

According to the second exemplary embodiment of the present disclosure, the overplated thickness ranges from 1 to 5 μm, but is not particularly limited thereto.

Since the plating seed layer 206 is also formed on the insulating layer 204 by the sputtering process, the electric conductivity is increased and thus the electroplating is performed without the problem of fillability at the time of the electroplating and the outermost portion of the electroplating layer 208 is formed to be planarized by the panel plating scheme.

Next, as illustrated in FIG. 2D, the overplated portion of the electroplating layer 208 and a portion of the plating seed layer 206 are etched in a lump. For example, the overplated portion of the electroplating layer 208 and a portion of the plating seed layer 206 are etched in a lump by the half etching. The etching is performed at 2 to 6 μm until the insulating layer 204 is exposed. When the etching is completed, a thickness of a first circuit pattern 209 formed of the electroplating layer 208 and the plating seed layer 206 becomes uniform while the outermost portion of the electroplating layer 208 and the plating seed layer 206 is planarized. Therefore, the first circuit pattern 209 having a uniform thickness may be formed.

Meanwhile, when the dry film resist (DFR) is used as the insulating layer 204, the insulating layer 204 is removed and then the portion from which the insulating layer 204 is removed may be formed with another insulating layer.

Next, as illustrated in FIG. 2E, an insulating layer 210, a plating seed layer 212, and an electroplating layer 214 are formed on the first circuit pattern 209 having a uniform thickness by using a similar process to the process illustrated in FIGS. 2A to 2D, thereby forming a via 213 having a uniform thickness.

Next, as illustrated in FIG. 2F, a second circuit pattern 216 is formed on the via 213 having a uniform thickness.

According to the second exemplary embodiment of the present disclosure, the substrate 200 is a carrier having both surfaces formed with the copper foils 202 which may be peeled.

Next, as illustrated in FIG. 2G, the printed circuit board including the plating layer having a uniform thickness may be manufactured by separating the carrier 200 from the stacked structure of the upper layer and the lower layer and removing the copper foils 202.

The second exemplary embodiment of the present disclosure describes the method for manufacturing a printed circuit board in which two and three layers are stacked but is not limited thereto, and therefore a multilayered printed circuit board may be manufactured by stacking a plurality of insulating layers and circuit layers having a uniform thickness.

Method for Manufacturing Printed Circuit Board According to Third Exemplary Embodiment

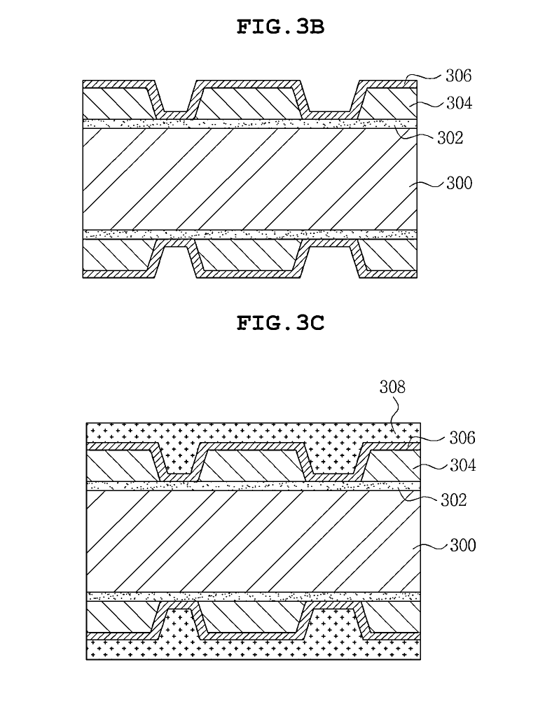

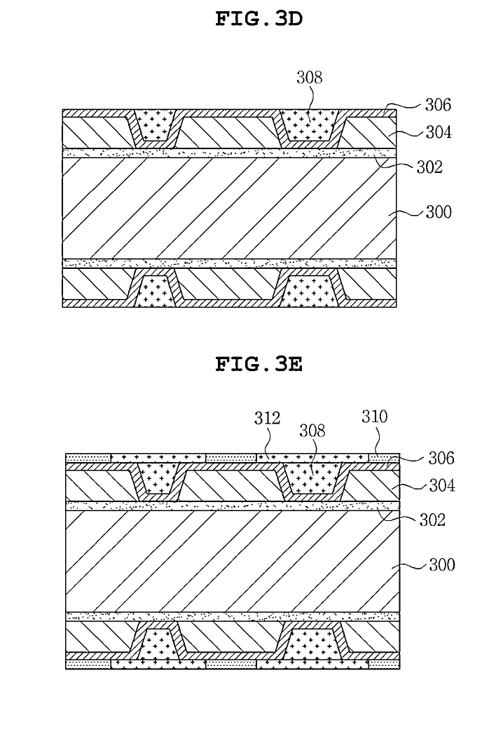

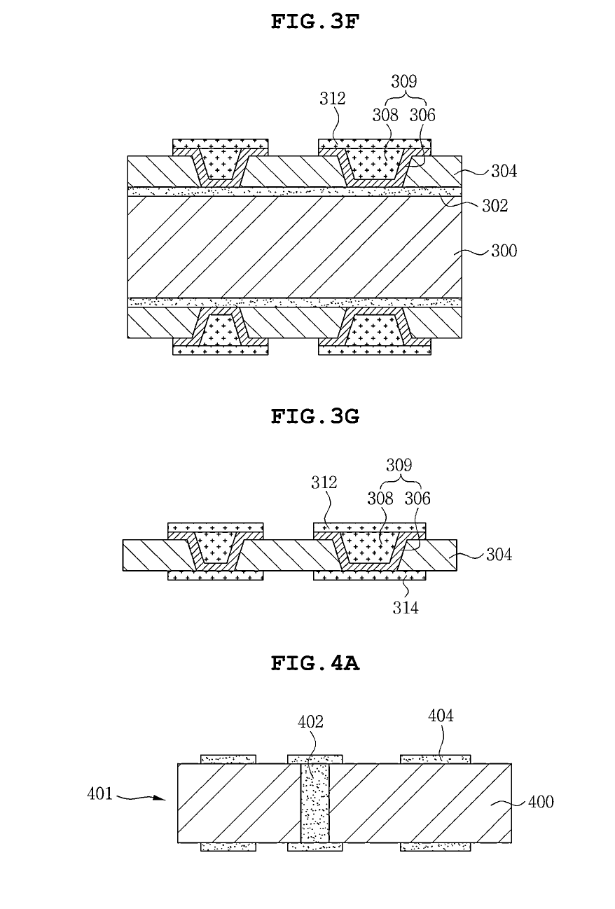

FIGS. 3A to 3G are process cross-sectional views sequentially illustrating a method for manufacturing a printed circuit board according to a third exemplary embodiment of the present disclosure.

Hereinafter, the method for manufacturing a printed circuit board according to the third exemplary embodiment of the present disclosure will be described with reference to FIGS. 3A to 3G.

Referring to FIG. 3A, a substrate 300 on which a copper foil 302 is formed is prepared and then an insulating layer 304 formed with an opening 305 through which a portion of the copper foil 300 is exposed is formed on the substrate 300. The insulating layer 304 is a stacked insulating film and may include a prepreg, but is not particularly limited thereto.

The opening 305 formed on the insulating layer 304 may be formed by laser processing after the insulating layer 304 is attached to the copper foil 302 formed on the substrate 300.

Next, as illustrated in FIG. 3B, the whole surface of the insulating layer 304 formed with the opening 305 and the base plating part 303 exposed through the opening 305 in the copper foil 302 is plated at 1 μm or less by the sputtering process, thereby forming a plating seed layer 306. The plating seed layer 306 may be formed by using the sputtering process or the electroless plating process.

According to the exemplary embodiment of the present disclosure, when the plating seed layer 306 is formed over the insulating layer 304 and the base plating part 303, a difference in electroplatability between the insulating layer 304 and the base plating part 303 is removed. Referring to FIG. 3B, it may be appreciated that the plating seed layer 306 is formed over the insulating layer 306, including sides of the insulating layer 304.

Next, as illustrated in FIG. 3C, the electroplating layer 308 is formed on the plating seed layer 306 by performing the electroplating. The plating seed layer 306 is overplated until a surface of the electroplating layer 308 is planarized by controlling a frequency of the electroplating and a current density. For example, the electroplating layer 308 is overplated so that an outermost portion of the plating seed layer 306 exceeds around 1 to 5 μm.

According to the third exemplary embodiment of the present disclosure, the overplated thickness ranges from 1 to 5 μm, but is not particularly limited thereto.

Since the plating seed layer 304 is also formed on the insulating layer 304 by the sputtering process, the electric conductivity is increased and thus the electroplating is performed without the problem of fillability at the time of the electroplating and the outermost portion of the electroplating layer 308 is formed to be planarized by the panel plating scheme.

Next, as illustrated in FIG. 3D, the overplated portion of the electroplating layer 308 is etched in a lump until the plating seed layer 306 is exposed. For example, the electroplating layer 308 is etched in a lump by the half etching. The etching is performed at 1 to 5 μm until the plating seed layer 306 is exposed. When the etching is completed, the outermost portion of the electroplating layer 308 and the plating seed layer 306 is planarized. Next, the plated thickness becomes uniform without the occurrence of the dimple and thus the circuit layer may be formed on the electroplating layer 308.

Unlike the first exemplary embodiment of the present disclosure, according to the third exemplary embodiment of the present disclosure, when the overplated portion of the electroplating layer 308 is etched, the etching is not performed until the insulating layer 304 is exposed but is etched in a lump until the plating seed layer 306 is exposed. This is to use the plating seed layer 306 and the electroplating layer 308 as the plating seed layer for forming the circuit layer in the subsequent processes.

According to the third exemplary embodiment of the present disclosure, the via for interlayer connection is formed by the electroplating layer 308 and the plating seed layer 306, but the thick circuit pattern may also be formed by the electroplating layer 308 and the plating seed layer 306.

Next, as illustrated in FIG. 3E, an insulating layer 310 formed with an opening is formed on the electroplating layer 308 and the plating seed layer 306 and the first circuit pattern 308 is formed in the opening.

Next, as illustrated in FIG. 3F, the insulating layer 310 and the plating seed layer 306 beneath the insulating layer 310 are etched to be removed, thereby forming the via 309 having a uniform thickness which are formed by the plating seed layer 306 and the electroplating layer 308, and the circuit pattern 312.

Meanwhile, according to the third exemplary embodiment of the present disclosure, the substrate 300 is a carrier having both surfaces formed with the copper foils 302 which may be peeled.

As illustrated in FIG. 3G, the carrier 300 is separated from the stacked structure of the upper layer and the lower layer, the copper foils 302 are removed, and then the second circuit pattern 314 is formed under the via 309 having a uniform thickness, such that the printed circuit board having a uniform thickness may be completed.

Method for Manufacturing Printed Circuit Board According to Fourth Exemplary Embodiment

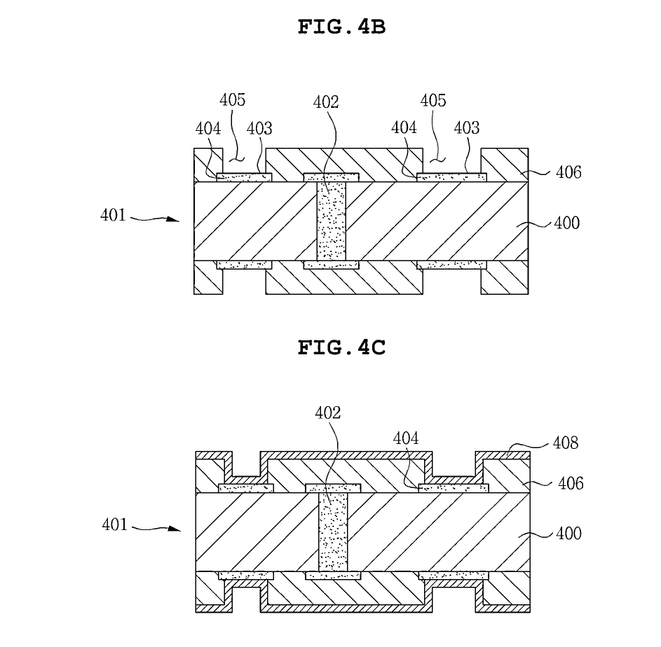

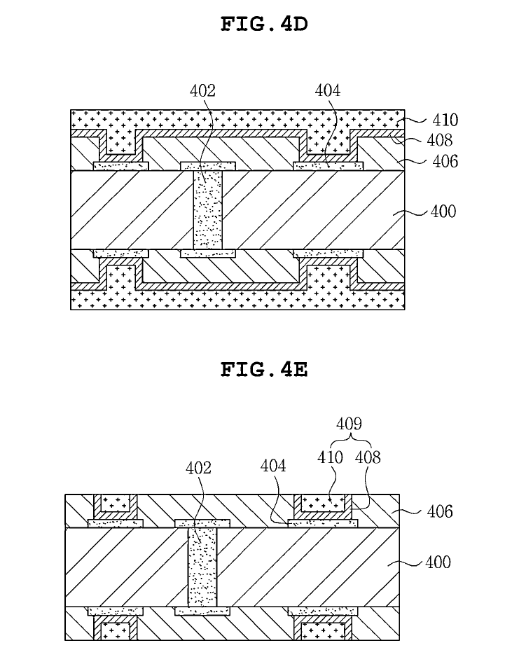

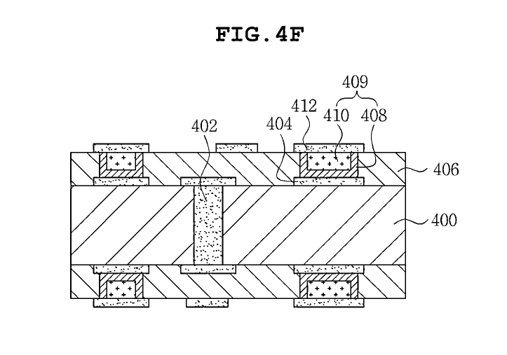

FIGS. 4A to 4F are process cross-sectional views illustrating a method for manufacturing a printed circuit board according to a fourth exemplary embodiment of the present disclosure.

Hereinafter, the method for manufacturing a printed circuit board according to the fourth exemplary embodiment of the present disclosure will be described with reference to FIGS. 4A to 4F.

According to a fourth exemplary embodiment of the present disclosure, a method for manufacturing a build-up printed circuit board which is formed by stacking insulating layers and circuit layers on and beneath of a printed circuit board 401 which includes a substrate 400, a via 402, and a circuit pattern 404 will be described.

As illustrated in FIG. 4A, the printed circuit board 401 which includes the substrate 400, the via 402, and the circuit pattern 404 is prepared.

Next, as illustrated in FIG. 4B, an insulating layer 406 formed with an opening 405 through which a portion of the circuit pattern 404 is exposed is formed on the substrate 401. The insulating layer 406 may include a liquid photosensitive resin as a photosensitive resin material or a dry film resist (DRF), but is not particularly limited thereto.

The opening 405 formed on the insulating layer 406 may be formed by the exposing and developing processes after the insulating layer 406 is attached to the substrate 400. According to the method for manufacturing a printed circuit board according to the fourth exemplary embodiment of the present disclosure, the photosensitive resin material is used as the insulating layer 406 and the opening 405 is formed on the insulating layer 406 by using the photo method which is the exposure method.

Next, as illustrated in FIG. 4C, the whole surface of the insulating layer 406 formed with the opening 405 and the base plating part 403 of the circuit pattern 404 exposed through the opening 405 are plated at 1 μm or less by the sputtering process, thereby forming a plating seed layer 408. The plating seed layer 408 may be formed by using the sputtering process or the electroless plating process.

According to the exemplary embodiment of the present disclosure, when the plating seed layer 408 is formed over the insulating layer 406 and the base plating part 403, a difference in electroplatability between the insulating layer 406 and the base plating part 403 is removed.

Next, as illustrated in FIG. 4D, an electroplating layer 410 is formed on the plating seed layer 408 by performing the electroplating. The plating seed layer 408 is overplated until a surface of the electroplating layer 410 is planarized by controlling a frequency of the electroplating and a current density at the time of the electroplating.

For example, the electroplating layer 410 is overplated so that an outermost portion of the plating seed layer 408 exceeds around 1 to 5 μm.

According to the fourth exemplary embodiment of the present disclosure, the overplated thickness ranges from 1 to 5 μm, but is not particularly limited thereto.

Since the plating seed layer 408 is also formed on the insulating layer 406 by the sputtering process, the electric conductivity is increased and thus the electroplating is performed without the problem of fillability at the time of the electroplating and the outermost portion of the electroplating layer 410 is formed to be planarized by the panel plating scheme.

Next, as illustrated in FIG. 4E, the overplated portion of the electroplating layer 410 is etched in a lump. For example, the overplated portion of the electroplating layer 410 and a portion of the plating seed layer 408 are etched in a lump by the half etching. The etching is performed at 2 to 6 μm until the insulating layer 406 is exposed. When the etching is completed, a thickness of the via 409 formed of the electroplating layer 410 and the plating seed layer 408 becomes uniform while the outermost portion of the electroplating layer 410 and the plating seed layer 408 is planarized. Therefore, the via 409 having a uniform thickness may be formed.

Meanwhile, when the dry film resist (DFR) is used as the insulating layer 406, the insulating layer 406 is removed and then the portion from which the insulating layer 406 is removed may be formed with another insulating layer.

Next, as illustrated in FIG. 4F, the circuit pattern 412 is formed on the via 409 having a uniform thickness, such that the build-up printed circuit board which is formed in a multilayer may be formed.

As described above, according to the exemplary embodiments of the present disclosure, when the plating layer for forming the circuit layer is formed by the electroplating scheme, to make the plated thickness uniform, the plating seed layer is formed on the insulating layer formed with the opening at the portion at which the via or the circuit pattern will be formed and the base plating part by the sputtering process, such that the electric conductivity between the insulating layer and the base plating part is similar. Next, the outermost portion of the plating seed layer is overplated to exceed around 1 to 5 μm to plate the panel and then is etched in a lump to make the plated thickness uniform, such that the thickness of the via or the circuit pattern may be uniform.

Therefore, the problem of the occurrence of the dimple and the non-uniformity of the plated thickness due to the wiring design which may occur in the electroplating scheme may be solved and therefore the number of manufacturing processes of the printed circuit board may be reduced. Further, since the mechanical polishing causing the warpage and scratch of the substrate is not used, the stress of the substrate may be reduced.

As set forth above, according to the exemplary embodiments of the present disclosure, it is possible to make the plated thickness of the via or the circuit layer uniform since the non-uniformity of the plated thickness and the occurrence of the dimple due to the difference in the ratio of length to width of the portion to be plated in response to the thickness of the stacked film or the dry film and the wiring design which may occur in the electroplating scheme may be solved and it is possible to reduce the stress of the substrate by preventing the warpage and scratch of the substrate since the mechanical polishing is not used.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A method for manufacturing a printed circuit board, the method comprising:
preparing a substrate having a conductive layer formed on at least a portion thereof;
forming an insulating layer formed with an opening through which a portion of the conductive layer is exposed on the substrate;
forming a plating seed layer on the insulating layer and the exposed conductive layer;
forming an electroplating layer on the plating seed layer by overplating the plating seed layer; and
etching the overplated portion in a lump to form a circuit layer in the opening.

2. The method of claim 1, wherein the forming of the electroplating layer includes overplating the plating seed layer until an exposed surface of the electroplating layer is planarized.

3. The method of claim 1, wherein the etching of the overplated portion in a lump includes etching the overplated portion in a lump until the insulating layer is exposed.

4. The method of claim 1, wherein the etching of the overplated portion in a lump includes etching the overplated portion in a lump so that the electroplating layer and the plating seed layer of 1 μm or less remains outside the insulating layer and the electroplating layer and the plating seed layer of 1 μm or less which are formed outside the insulating layer serve as the plating seed layer for forming additional circuit layer.

5. The method of claim 1, wherein the forming of the plating seed layer includes forming the plating seed layer on the insulating layer and the exposed conductive layer by an electroless plating process or a sputtering process.

6. The method of claim 1, wherein in the etching of the overplated portion in a lump, the circuit layer formed in the opening by the etching in a lump includes a via or a circuit pattern.

7. The method of claim 1, wherein the conductive layer includes a via or a circuit pattern.

8. The method of claim 1, wherein the conductive layer includes a copper foil formed over the substrate,
wherein the method further comprises:
after the etching of the overplated portion in a lump, removing the insulating layer and a copper foil contacting the insulating layer by an etching process and forming a stacked insulating layer at the removed position.

9. The method of claim 1, wherein the insulating layer includes a photosensitive resin material, and
the opening of the insulating layer is formed by attaching the photosensitive resin material to the substrate and by exposing and developing processes.

10. The method of claim 1, wherein the insulating layer includes a stacked film, and
the opening of the insulating layer is formed by attaching the stacked film to the substrate and by laser processing.

11. A method for manufacturing a printed circuit board, comprising:
preparing a carrier having both surfaces formed with copper foils formed to be peeled;
forming an insulating layer formed with an opening through which a portion of the copper foil is exposed on the carrier;
forming a plating seed layer on the insulating layer and the exposed copper foil;
forming an electroplating layer on the plating seed layer by overplating the plating seed layer;
etching the overplated portion in a lump to form a circuit layer in the opening;
stacking a plurality of insulating layers and circuit layers on the circuit layer;
separating the carrier from a stacked structure of an upper layer and a lower layer; and
removing the copper foils of the carrier which are each attached to the stacked structure of the upper layer and the lower layer.

12. The method of claim 11, wherein the forming of the electroplating layer includes overplating the plating seed layer until an exposed surface of the electroplating layer is planarized.

13. The method of claim 11, wherein the etching of the overplated portion in a lump includes etching the overplated portion in a lump until the insulating layer is exposed.

14. The method of claim 11, wherein the etching of the overplated portion in a lump includes etching the overplated portion in a lump so that the electroplating layer and the plating seed layer of 1 μm or less remains outside the insulating layer and the electroplating layer and the plating seed layer of 1 μm or less which are formed outside the insulating layer serve as the plating seed layer for forming additional circuit layer.

15. The method of claim 11, wherein the forming of the plating seed layer includes forming the plating seed layer on the insulating layer and the exposed copper foil by an electroless plating process or a sputtering process.

16. The method of claim 11, wherein in the etching of the overplated portion in a lump, the circuit layer formed in the opening by the etching in a lump includes a via or a circuit pattern.

17. The method of claim 11, wherein the insulating layer includes a photosensitive resin material, and
the opening of the insulating layer is formed by attaching the photosensitive resin material to the copper foil and by exposing and developing processes.

18. The method of claim 11, wherein the insulating layer includes a stacked film, and
the opening of the insulating layer is formed by attaching the stacked film to the copper foil and by laser processing.

19. A printed circuit board, comprising:
an insulating layer formed with at least one opening; and
a circuit layer formed in the at least one opening,
wherein the circuit layer includes:
a plating seed layer including a bottom portion and side walls surrounded with the insulating layer; and
an electroplating layer surrounded with the bottom portion and the side walls of the plating seed layer.

20. The printed circuit board of claim 19, wherein the circuit layer includes a via or a circuit pattern, and
the via or the circuit pattern is formed by forming the plating seed layer on the insulating layer and a portion exposed by the opening, forming an electroplating layer by overplating the plating seed layer, and etching the overplated portion in a lump.
